(19) United States
(12) Patent Application Publication
(10) Pub. No.: US 2015/0123153 A1
(43) Pub. Date: May 7, 2015

(54) LED PACKAGE WITH RED-EMITTING PHOSPHORS

(71) Applicant: GENERAL ELECTRIC COMPANY, Schenectady, NY (US)

(72) Inventors: Anant Achyut Setlur, Niskayuna, NY (US); James Edward Murphy, Niskayuna, NY (US); Florencio Garcia, Schenectady, NY (US)

(73) Assignee: GENERAL ELECTRIC COMPANY, Schenectady, NY (US)

(21) Appl. No.: 14/073,141

(22) Filed: Nov. 6, 2013

(51) Int. Cl. H01L 33/50; H01L 33/00

(52) U.S. Cl. CPC H01L 33/502; H01L 33/005; H01L 2933/0066
USPC 257/98; 438/29

(57) ABSTRACT

A process for fabricating an LED lighting apparatus comprising a color stable Mn⁴⁺ doped phosphor of formula I includes forming on a surface of an LED chip a polymer composite layer comprising a first and a second population of particles of the phosphor of formula I having a graded composition varying in manganese concentration across a thickness thereof;

Aₓ(M,Mn)F_{y} (I)

wherein
A is Li, Na, K, Rb, Cs, NR₄ or a combination thereof;
M is Si, Ge, Sn, Ti, Zr, Al, Ga, In, Sc, Hf, Y, La, Nb, Ta, Bi, Gd, or a combination thereof;
R is H, lower alkyl, or a combination thereof;
x is the absolute value of the charge of the [MF_{y}] ion; and
y is 5, 6 or 7.
   The first population of particles has a lower manganese concentration than the second population of particles, and the manganese concentration in the polymer composite layer ranges from a minimum value in a region of the polymer composite layer proximate to the LED chip to a maximum value in a region opposite to the LED chip.

### BACKGROUND

Red-emitting phosphors based on complex fluoride materials activated by Mn⁴⁺, such as those described in U.S. Pat. No. 7,358,542, U.S. Pat. No. 7,497,973, and U.S. Pat. No. 7,648,649, can be utilized in combination with yellow/green emitting phosphors such as YAG:Ce or other garnet compositions to achieve warm white light (CCTs<5000 K on the blackbody locus, color rendering index (CRI)>80) from a blue LED, equivalent to that produced by current fluorescent, incandescent and halogen lamps. These materials absorb blue light strongly and efficiently emit between about 610-635 nm with little deep red/NIR emission. Therefore, luminous efficacy is maximized compared to red phosphors that have significant emission in the deeper red where eye sensitivity is poor. Quantum efficiency can exceed 85% under blue (440-460 nm) excitation.

While the efficacy and CRI of lighting systems using Mn⁴⁺ doped fluoride hosts can be quite high, one potential limitation is their susceptibility to degradation under use conditions. It is possible to reduce this degradation using post-synthesis processing steps, as described in U.S. Pat. No. 8,252,613. However, development of alternative methods for improving stability of the materials is desirable.

### BRIEF DESCRIPTION

Briefly, in one aspect, the present invention relates to a process for fabricating an LED lighting apparatus that includes a color stable Mn⁴⁺ doped phosphor of formula I

Aₓ(M,Mn)F_{y} (I)

wherein
A is Li, Na, K, Rb, Cs, NR₄ or a combination thereof;
M is Si, Ge, Sn, Ti, Zr, Al, Ga, In, Sc, Hf, Y, La, Nb, Ta, Bi, Gd, or a combination thereof;
R is H, lower alkyl, or a combination thereof;
x is the absolute value of the charge of the [MF_{y}] ion; and
y is 5, 6 or 7.

The process includes forming on a surface of an LED chip a polymer composite layer comprising a first and a second population of particles of the phosphor of formula I. The polymer composite layer has a graded composition varying in manganese concentration across a thickness thereof, the first population of particles has a lower manganese concentration than the second population of particles, and the manganese concentration in the polymer composite layer ranges from a minimum value in a region of the polymer composite layer proximate to the LED chip to a maximum value in a region opposite to the LED chip.

In another aspect, an LED lighting apparatus according to the present invention includes an LED chip and a polymer composite layer disposed on a surface of the LED chip and comprising a Mn⁴⁺-doped complex fluoride phosphor of formula I. The composition of the polymer composite layer varies in manganese concentration across a thickness thereof; and the manganese concentration ranges from a minimum value in a region of the polymer composite layer proximate to the LED chip to a maximum value in a region opposite to the LED chip.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic cross-sectional view of a lighting apparatus according to the present invention.

FIG. 2 is a schematic cross-sectional view through the LED chip and chip coating of a lighting apparatus according to an embodiment of the present invention.

FIG. 3 is a schematic cross-sectional view through the LED chip and chip coating of a lighting apparatus according to another embodiment of the present invention.

### DETAILED DESCRIPTION

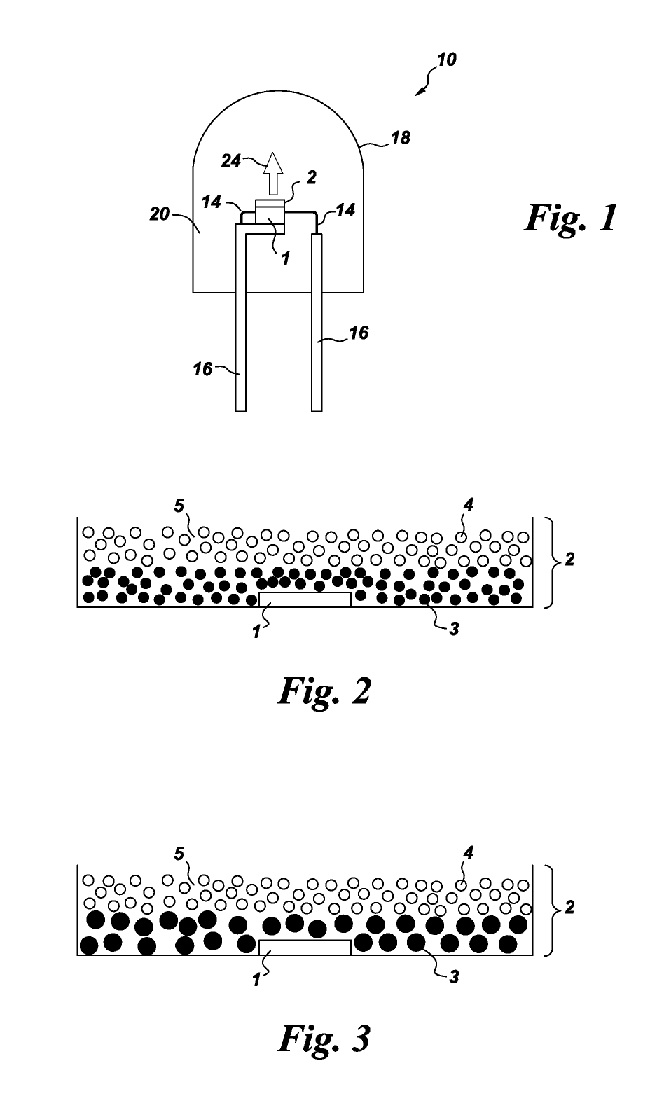

A cross sectional view of a lighting apparatus or light emitting assembly or lamp 10 according to the present invention is shown in FIG. 1. Lighting apparatus 10 includes a semiconductor radiation source, shown as light emitting diode (LED) chip 1, and leads 14 electrically attached to the LED chip. The leads 14 may be thin wires supported by a thicker lead frame(s) 16 or the leads may be self-supported electrodes and the lead frame may be omitted. The leads 14 provide current to LED chip 1 and thus cause it to emit radiation.

LED chip 1 may be any semiconductor blue or ultraviolet light source that is capable of producing white light when its emitted radiation is directed onto the phosphor. In particular, the semiconductor light source may be a blue emitting LED semiconductor diode based on a nitride compound semiconductor of formula InᵢGaⱼAlₖN (where 0≦i; 0≦j; 0≦k and l+j+k=1) having an emission wavelength greater than about 250 nm and less than about 550 nm. More particularly, the chip may be a near-uv or blue emitting LED having a peak emission wavelength from about 400 to about 500 nm. Even more particularly, the chip may be a blue emitting LED having a peak emission wavelength ranging from about 440-460 nm Such LED semiconductors are known in the art.

In lighting apparatus 10, polymer composite layer 2 is disposed on a surface of LED chip 1. The polymer composite layer 2 includes a Mn⁴⁺-doped complex fluoride phosphor of formula I and is radiationally coupled to the chip. Radiationally coupled means that radiation from LED chip 1 is transmitted to the phosphor, and the phosphor emits radiation of a different wavelength. In a particular embodiment, LED chip 1 is a blue LED, and polymer composite layer 2 includes a blend of a red line emitting phosphor of formula 1 and a yellow-green phosphor such as a cerium-doped yttrium aluminum garnet, Ce:YAG. The blue light emitted by the LED chip 1 mixes with the red and yellow-green light emitted by the phosphors of polymer composite layer 2, and the emission (indicated by arrow 24) appears as white light.

LED chip 1 may be enclosed by an encapsulant material 20. The encapsulant material 20 may be a low temperature glass, or a thermoplastic or thermoset polymer or resin as is known in the art, for example, a silicone or epoxy resin. LED chip 1 and encapsulant material 20 may be encapsulated within shell 18. In addition, scattering particles may be embedded in the encapsulant material. The scattering particles may be, for example, alumina or titania. The scattering particles effectively scatter the directional light emitted from the LED chip, preferably with a negligible amount of absorption. In some embodiments, the encapsulant material 20 contains a diluent material having less than about 5% absorbance and index of refraction of R±0.1. Adding an optically inactive material to the phosphor/silicone mixture may produce a more gradual distribution of flux across the tape and can result in less damage to the phosphor. Suitable materials for the diluent include cubic fluoride compounds such as LiF, MgF₂, CaF₂, SrF₂, AlF₃, K₂NaAlF₆, KMgF₃, CaLiAlF₆, KLiAlF₆, and K₂SiF₆, which have index of refraction ranging from about 1.38 (AlF₃ and K₂NaAlF₆) to about 1.43 (CaF₂), and polymers having index of refraction ranging from about 1.254 to about 1.7. Non-limiting examples of polymers suitable for use as a diluent include polycarbonates, polyesters, nylons, polyetherimides, polyetherketones, and polymers derived from styrene, acrylate, methacrylate, vinyl, vinyl acetate, ethylene, propylene oxide, and ethylene oxide monomers, and copolymers thereof, including halogenated and unhalogenated derivatives. These polymer powders can be directly incorporated into silicone encapsulants before silicone curing.

In an alternate embodiment, the lamp 10 may only include an encapsulant material without an outer shell 18. The LED chip 1 may be supported, for example, by the lead frame 16, by the self-supporting electrodes, the bottom of shell 18 or by a pedestal (not shown) mounted to shell 18 or to the lead frame.

FIG. 2 is an idealized cross section through LED chip 1 and polymer composite layer 2 showing that polymer composite layer 2 is composed of a first population 3 of particles of a Mn⁴⁺-doped complex fluoride phosphor of formula I and a second population 4 of particles of the same phosphor, dispersed in a polymer composite matrix material 5. Particles of the first population 3 have a lower manganese concentration than particles of the second population 4 of particles. The concentration of manganese in first population of particles ranges from greater than 0 mol % to about 3 mol %, particularly from 1 mol % to about 3 mol %, and more particularly, from about 1 mol % to about 2.5 mol %, and the concentration of manganese in the particles of second population 4 ranges from about 2 mol % to about 5 mol %, and particularly from 2 mol % to about 4 mol %. The amount of manganese in the particles of first population 3 is less than that in the particles of second population 4. For example, when the concentration of manganese in first population of particles is 2.5 mol %, the concentration of manganese in the particles of second population 4 ranges from greater than 2.5 to about 5 mol %. Or when the concentration of manganese in the particles of second population 4 is 2 mol %, then the concentration of manganese in first population of particles is less than 2 mol %. In particular embodiments, the first population 3 is composed of a phosphor of formula K₂(Siₐ,Mn_{b})F₆ where a ranges from 0.975 to 0.99 and b ranges from 0.01 to 0.025, and a+b=1, and the second population 4 is composed of a phosphor of formula K₂(Si_{c},Mn_{d})F₆ where c ranges from 0.95 to 0.98 and d ranges from 0.02 to 0.05, and c+d=1.

Polymer composite layer 2 has a graded composition varying in manganese concentration across a thickness thereof, that is, in a direction normal to the plane of the surface of LED chip 1, with the manganese concentration ranging from a minimum value in a region proximate to the LED chip to a maximum value in a region opposite to the LED chip. The particles may be disposed in a band structure, where the first population of particles having a lower manganese concentration is located generally in a region of the polymer composite layer proximate to the LED chip and the second population of particles generally located in a region opposite to the LED chip. The layer may not have a distinct interface at which the composition changes abruptly. Particles of the first population 3 may be mixed with particles of the second population 4 throughout polymer composite layer 2; however, in all embodiments, the layer has a graded manganese composition, with a lower concentration of manganese in the region closest to LED chip 1.

A lighting apparatus according to the present invention is fabricated by forming a polymer composite layer that includes the first and second populations of particles of the Mn⁴⁺-doped complex fluoride phosphor of formula I on a surface of an LED chip. The particles may be dispersed in a polymer or polymer precursor, particularly a silicone or silicone epoxy resin or precursors therefor. Such materials are well known for LED packaging and will not be described in detail herein. The dispersion is coated on the chip by any suitable process, and particles having a larger density or particle size, or a larger density and larger particle size, preferentially settle in the layer to the region proximate the LED chip, forming a layer having a graded composition. Settling may occur during the coating or curing of the polymer or precursor, and may be facilitated by a centrifuging process. In a first embodiment, the particles of the first and second populations differ in density, and density of particles of the first population is greater than density of particles of the second population. In a second embodiment, the particles of the first and second populations differ in particle size, and the median particle size of the first population of particles is greater than median particle size of the second population of particles.

Alternately, the polymer composite layer may be formed by a two-step coating process. Particles of the first population are dispersed in a polymer resin or resin precursor to form a first coating composition, and particles of the second population are dispersed in a polymer resin or resin precursor to form a second coating composition. The first coating composition is disposed on the LED chip, dried and optionally cured, then the second coating composition is disposed on the first to form a polymer composite layer that includes two layers, particles of the first layer having a lower Mn content than those of the second layer. Where a two-step coating process is used, particles of the first population may have a particle size or density, or particle size and density that is the same as or different from those of the second population.

In some embodiments, the particles of the first populations differ in density and manganese content from the particles of the second population, and particles of the first population have a lower density and lower manganese concentration than particles of the second population of particles. Density of the particles of the first population ranges from about 2.5 g/cc to about 4.5 g/cc. Density of the particles of the second population ranges from about 2.5 g/cc to about 4.5 g/cc. In particular embodiments, density of the particles of the first population ranges from about 2.5 g/cc to about 4.5 g/cc, and concentration of manganese therein ranges from about 1 mol % to about 2.5 mol %, density of the particles of the second population ranges from about 2.5 g/cc to about 4.5 g/cc, and concentration of manganese therein in ranges from about 2 mol % to about 5 mol %, with the condition that the density of the first population of particles is greater than the second population of particles and the median particle sizes are within 10% of one another.

FIG. 3 illustrates an embodiment where the particles of the first and second populations differ in particle size as well as manganese concentration. Polymer composite layer 2 is composed of a first population 3 of particles having a median particle size greater than particles of a second population 4 of particles of the same phosphor, dispersed in a polymer composite matrix material 5. Particle size of the particles of first population 3 is greater than that of the particles of the second population 4, and manganese concentration is lower. The median particle size of the particles of first population 3 ranges from about 10 um to about 100 um, particularly from about 20 um to about 50 um. The median particle size of the particles of second population 4 ranges from about 1 um to about 50 um, particularly from about 10 um to about 30 um.

In addition to the Mn⁴⁺ doped phosphor, polymer composite layer 2 may include one or more other phosphors to produce color point, color temperature, or color rendering as desired. When used in a lighting apparatus in combination with a blue or near UV LED emitting radiation in the range of about 250 to 550 nm, the resultant light emitted by the assembly will be a white light. Other phosphors such as green, blue, orange, or other color phosphors may be used in the blend to customize the white color of the resulting light and produce higher CRI sources.

Suitable phosphors for use along with the phosphor of formula I include, but are not limited to:
((Sr_{1-z}(Ca,Ba,Mg,Zn)_{z})_{1-(x+w)}(Li,Na,K,Rb)_{w}Ceₓ)₃(Al_{1-y}Si_{y})O_{4+y+3(x-w)}F_{1-y-3(x-w)}, 0<x≦0.10, 0≦y≦0.5, 0≦z≦0.5, 0≦w≦x;
(Ca,Ce)₃Sc₂Si₃O₁₂(CaSiG);
(Sr,Ca,Ba)₃Al₁₋ₓSiₓO₄₊ₓF₁₋ₓ:Ce³⁺((Ca,Sr,Ce)₃(Al,Si)(O,F)₅(SASOF));
(Ba,Sr,Ca)₅(PO₄)₃(Cl,F,Br,OH):Eu²⁺,Mn²⁺; (Ba,Sr,Ca)BPO₅:Eu²⁺,Mn²⁺;
(Sr,Ca)₁₀(PO₄)₆*νB₂O₃:Eu²⁺ (wherein 0<ν≦1); Sr₂Si₃O₈*2SrCl₂:Eu²⁺;
(Ca,Sr,Ba)₃MgSi₂O₈:Eu²⁺,Mn²⁺; BaAl₈O₁₃:Eu²⁺; 2SrO*0.84P₂O₅*0.16B₂O₃:Eu²⁺;
(Ba,Sr,Ca)MgAl₁₀O₁₇:Eu²⁺,Mn²⁺; (Ba,Sr,Ca)Al₂O₄:Eu²⁺; (Y,Gd,Lu,Sc,La)BO₃:Ce³⁺,Tb³⁺;
ZnS:Cu⁺,Cl⁻; ZnS:Cu⁺,Al³⁺; ZnS:Ag⁺,Cl⁻; ZnS:Ag⁺,Al³⁺; (Ba,Sr,Ca)₂Si_{1-ξ}O_{4-2ξ}:Eu²⁺ (wherein 0≦ξ0.2); (Ba,Sr,Ca)₂(Mg,Zn)Si₂O₇:Eu²⁺; (Sr,Ca,Ba)(Al,Ga,In)₂S₄:Eu²⁺;
(Y,Gd,Tb,La,Sm,Pr,Lu)₃(Al,Ga)_{5-α}O_{12-3/2α}:Ce⁺³ (wherein 0≦α≦0.5);
(Ca,Sr)₈(Mg,Zn)(SiO₄)₄Cl₂:Eu²⁺,Mn²⁺; Na₂Gd₂B₂O₇:Ce³⁺,Tb³⁺;
(Sr,Ca,Ba,Mg,Zn)₂P₂O₇:Eu²⁺,Mn²⁺; (Gd,Y,Lu,La)₂O₃:Eu³⁺,Bi³⁺;
(Gd,Y,Lu,La)₂O₂S:Eu³⁺,Bi³⁺; (Gd,Y,Lu,La)VO₄:Eu³⁺,Bi³⁺; (Ca,Sr)S:Eu²⁺,Ce³⁺; SrY₂S₄:Eu²⁺;
CaLa₂S₄:Ce³⁺; (Ba,Sr,Ca)MgP₂O₇:Eu²⁺,Mn²⁺; (Y,Lu)₂WO₆:Eu³⁺,Mo⁶⁺;
(Ba,Sr,Ca)_{β}Si_{≢}N_{μ}:Eu²⁺ (wherein 2β+4γ=3μ); Ca₃(SiO₄)Cl₂:Eu²⁺;
(Lu,Sc,Y,Tb)₂₋ᵤ₋ᵥCeᵥCa₁₊ᵤLi_{w}Mg_{2-w}P_{w}(Si,Ge)_{3-w}O_{12-u/2} (where −0.5≦u≦1, 1<v≦0.1, and 0≦w≦0.2); (Y,Lu,Gd)_{2-Φ}Ca_{Φ}Si₄N_{6+Φ}:Ce³⁺, (wherein 0≦Φ≦0.5); (Lu,Ca,Li,Mg,Y), α-SiAlON doped with Eu²⁺ and/or Ce³⁺; β-SiAlON:Eu²⁺; (Ca,Sr,)AlSiN₃:Eu²⁺ (Ca,Sr,Ba)SiO₂N₂:Eu²⁺,Ce³⁺; 3.5MgO*0.5MgF₂*GeO₂:Mn⁴⁺; Ca_{1-c-f}Ce_{c}Eu_{f}Al_{1+c}Si_{1-c}N₃, (where 023 c≦0.2, 0≦f≦0.2); Ca₁₋ₕ₋ᵣCeₕEuᵣAl₁₋ₕ(Mg,Zn)ₕSiN₃, (where 0≦h≦0.2, 0≦r≦0.2); Ca₁₋₂ₛ₋ₜCeₛ(Li,Na)ₛEuₜAlSiN₃, (where 0≦s≦0.2, 0≦f≦0.2, s+t>0); and Ca_{1-σ-χ-φ}Ce_{σ}(Li,Na)_{χ}Eu_{φ}Al_{1+σ-χ}N₃, (where 0≦σ≦0.2, 0≦χ≦0.4, 0≦φ≦0.2).
   In particular, suitable phosphors for use in blends with the phosphor of formula I are (Ca,Ce)₃Sc₂Si₃O₁₂(CaSiG);
(Sr,Ca,Ba)₃Al₁₋ₓSiₓO₄₊ₓF₁₋ₓ:Ce⁺((Ca,Sr,Ce)₃(Al,Si)(O,F)₅(SASOF));
(Ba,Sr,Ca)₂Si_{1-ξ}O_{4-2ξ}:Eu²⁺ (wherein 0≦ξ≦0.2);
(Y,Gd,Tb,La,Sm,Pr,Lu)₃(Al,Ga)_{5-α}O_{12-3/2α}:Ce³⁺ (wherein 0≦α≦0.5);
(Ba,Sr,Ca)₆₂Si_{γ}N_{μ}:Eu²⁺ (wherein 2β+4γ=3μ); (Y,Lu,Gd)_{2-Φ}Ca_{Φ}Si₄N_{6+Φ}C_{1-φ}:Ce³⁺, (wherein 0≦Φ≦0.5); β-SiAlON:Eu²⁺; and (Ca,Sr,)AlSiN₃:Eu²⁺.
   More particularly, a phosphor that emits yellow-green light upon excitation by the LED chip may be included in a phosphor blend with a phosphor of formula I, for example a Ce-doped YAG, (Y,Gd,Tb,La,Sm,Pr,Lu)₃(Al,Ga)₅₋.O_{12-3/2}.:Ce³⁺ (wherein 0≦.≦0.5).

The ratio of each of the individual phosphors in the phosphor blend may vary depending on the characteristics of the desired light output. The relative proportions of the individual phosphors in the various embodiment phosphor blends may be adjusted such that when their emissions are blended and employed in an LED lighting device, there is produced visible light of predetermined x and y values on the CIE chromaticity diagram. Light produced may, for instance, may possess an x value in the range of about 0.30 to about 0.55, and a y value in the range of about 0.30 to about 0.55. As stated, however, the exact identity and amounts of each phosphor in the phosphor composition can be varied according to the needs of the end user.

### EXAMPLE

### Bimodal PS PFS Tape

K₂SiF₆Mn (5 mol % Mn, particle size 20 um) is combined with K₂SiF₆:Mn (2 mol % Mn, particle size 35 um) and the phosphor blend (500 mg) is mixed with a silicone precursor (Sylgard 184, 1.50 g). The mixture is degassed in a vacuum chamber for about 15 minutes. The mixture (0.70 g) is poured into a disc-shaped template (28.7 mm diameter and 0.79 mm thick), held for one hour, and baked for 30 minutes at 90° C. The sample was cut into 5×5 mm² squares for testing.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A process for fabricating an LED lighting apparatus comprising a Mn⁴⁺-doped complex fluoride phosphor of formula I,
Aₓ(M,Mn)F_{y} (I)
the process comprising forming on a surface of an LED chip a polymer composite layer comprising a first and a second population of particles of the Mn⁴⁺-doped complex fluoride phosphor of formula I;
wherein
the polymer composite layer has a graded composition varying in manganese concentration across a thickness thereof;
the first population of particles has a lower manganese concentration than the second population of particles; and
the manganese concentration in the polymer composite layer ranges from a minimum value in a region of the polymer composite layer proximate to the LED chip to a maximum value in a region opposite to the LED chip.

2. A process according to claim 1, wherein the concentration of manganese in first population of particles ranges from about 1 mol % to about 2.5 mol %, and the concentration of manganese in the second population of particles ranges from about 2 mol % to about 5 mol %.

3. A process according to claim 1, wherein median particle size of the first population of particles is greater than median particle size of the second population of particles.

4. A process according to claim 3, wherein the median particle size of the particles of the first population ranges from about 20 um to about 50 um.

5. A process according to claim 3, wherein the median particle size of the particles of second population ranges from about 10 um to about 30 um.

6. A process according to claim 1, wherein density of particles of the first population is greater than density of particles of the second population.

7. A process according to claim 6, wherein density of the particles of the first population ranges from about 2.5 g/cc to about 4.5 g/cc.

8. A process according to claim 6, wherein density of the particles of the second population ranges from about 2.5 g/cc to about 4.5 g/cc.

9. A process according to claim 1, wherein the Mn⁴⁺-doped complex fluoride phosphor of formula I is K₂(Si,Mn)F₆.

10. An LED lighting apparatus fabricated by a process according to claim 1.

11. An LED lighting apparatus comprising
an LED chip; and
a polymer composite layer disposed on a surface of the LED chip and comprising a Mn⁴⁺-doped complex fluoride phosphor of formula I,
Aₓ(M,Mn)F_{y} (I)
wherein
composition of the polymer composite layer varies in manganese concentration across a thickness thereof; and
the manganese concentration ranges from a minimum value in a region of the polymer composite layer proximate to the LED chip to a maximum value in a region opposite to the LED chip.

12. An LED lighting apparatus according to claim 11, wherein the Mn⁴⁺-doped complex fluoride phosphor of formula I is K₂(Si,Mn)F₆.

13. An LED lighting apparatus according to claim 11, wherein the polymer composite layer comprises a first and a second population of particles of the Mn⁴⁺-doped complex fluoride phosphor of formula I, and the first population of particles has a lower manganese concentration than the second population of particles.

14. An LED lighting apparatus according to claim 13, wherein a plurality of particles of the first population is disposed in a region of the polymer composite layer adjacent to the LED chip and a plurality of particles of the second population is disposed in a region of the polymer composite layer opposite to the LED chip.

15. An LED lighting apparatus according to claim 13, wherein the concentration of manganese in first population of particles ranges from about 1 mol % to about 2.5 mol %, and the concentration of manganese in the second population of particles ranges from about 2 mol % to about 5 mol %.

16. An LED lighting apparatus according to claim 13, wherein median particle size of the first population of particles is greater than median particle size of the second population of particles.

17. An LED lighting apparatus according to claim 16, wherein the median particle size of the particles of the first population ranges from about 20 um to about 50 um.

18. An LED lighting apparatus according to claim 16, wherein the median particle size of the particles of second population ranges from about 10 um to about 30 um.

19. An LED lighting apparatus according to claim 13, wherein density of particles of the first population is greater than density of particles of the second population.

20. An LED lighting apparatus according to claim 19, wherein density of the particles of the first population ranges from about 2.5 g/cc to about 4.5 g/cc.

21. An LED lighting apparatus according to claim 19, wherein density of the particles of the second population ranges from about 2.5 g/cc to about 4.5 g/cc.
